(19) United States
(12) Patent Application Publication
(10) Pub. No.: US 2021/0151394 A1
(43) Pub. Date: May 20, 2021

(54) SEMICONDUCTOR DEVICE AND METHOD OF MANUFACTURING THE SAME

(71) Applicant: RENESAS ELECTRONICS CORPORATION, Tokyo (JP)

(72) Inventors: Shinichi UCHIDA, Tokyo (JP); Yasutaka NAKASHIBA, Tokyo (JP)

(21) Appl. No.: 17/095,277

(22) Filed: Nov. 11, 2020

(30) Foreign Application Priority Data
Nov. 18, 2019 (JP) 2019-207599

(51) Int. Cl. H01L 23/64; H02J 50/12; H04B 5/00; H01L 49/02; H01L 21/56

(52) U.S. Cl. CPC H01L 23/645; H02J 50/12; H01L 21/56; H04B 5/0075; H01L 28/10; H04B 5/0037

(57) ABSTRACT

The semiconductor device includes a first semiconductor substrate having a first surface and a second surface having a relationship with each other, a first circuit and electrically connected to the first circuit, and a first inductor formed at a position overlapping with the first semiconductor substrate, between the first surface and the first circuit, a first chip formed so as to cover the first surface, a second semiconductor substrate having a third surface and a fourth surface having a relationship with each other, a second circuit and electrically connected, and a second inductor formed so as to be electromagnetically coupled with the first inductor, the second surface, grooves are formed to reach the first insulating film, in a plan view, It is formed so as to surround the first circuit.

### CROSS-REFERENCE TO RELATED APPLICATIONS

The disclosure of Japanese Patent Application No. 2019-207599 filed on Nov. 18, 2019 including the specification, drawings and abstract is incorporated herein by reference in its entirety.

### BACKGROUND

The present invention relates to a semiconductor device and a manufacturing method thereof, and, for example, to a semiconductor device having an inductor and a manufacturing method thereof.

In the power semiconductor device for power, a voltage of about several hundred volts is handled. On the other hand, in the semiconductor device for a microcomputer, a voltage of about several V is handled. To control the power semiconductor element for power by a semiconductor device having a microcomputer, between a circuit including a power semiconductor element, and a circuit including a semiconductor element for a microcomputer, it may perform transmission and reception of signals.

As a semiconductor device in which the reference voltage mediates transmission and reception of signals between semiconductor elements different from each other, so-called, digital isolator is used. In a digital isolator, a signal is transmitted between an inductor connected to a circuit including a power semiconductor element and an inductor connected to a circuit including a semiconductor element for a microcomputer.

In this regard, there are disclosed techniques below.

[PATENT DOCUMENT 1] Japanese Unexamined Patent Application Publication No. 2010-219120

[PATENT DOCUMENT 2] Japanese Unexamined Patent Application Publication No. 2015-095469

### SUMMARY

In conventional digital isolators, dielectric breakdown may occur in semiconductor devices due to differences in reference voltages. Therefore, there is room for improvement from the viewpoint of increasing the reliability of the semiconductor device.

Other objects and novel features will become apparent from the description of this specification and the accompanying drawings.

According to the semiconductor device according to the embodiment, it is possible to improve the reliability of the semiconductor device.

### BRIEF DESCRIPTION OF THE DRAWINGS

FIG. 1 is a circuit diagram of an electronic device according to a first embodiment;

FIG. 2 is an example of a plan view of the main portion of the semiconductor device according to the first embodiment;

FIG. 3 is an example of a cross-sectional view of the main portion of the semiconductor device according to the first embodiment;

FIG. 4 is an example of a cross-sectional view of a main part of the semiconductor device according to the first embodiment;

FIG. 5 is an example of a cross-sectional view showing a configuration example of a semiconductor device for comparison;

FIG. 6 is an example of a cross-sectional view of a main part in the manufacturing process of the semiconductor device of the first embodiment;

FIG. 7 is an example of a cross-sectional view of the main part during the manufacturing process of the semiconductor device following FIG. 6;

FIG. 8 is an example of a cross-sectional view of the main part during the manufacturing process of the semiconductor device following FIG. 7;

FIG. 9 is an example of a cross-sectional view of the main part during the manufacturing process of the semiconductor device following FIG. 8;

FIG. 10 is an example of a cross-sectional view of the main part during the manufacturing process of the semiconductor device following FIG. 9;

FIG. 11 is an example of a cross-sectional view of the main part during the manufacturing process of the semiconductor device following FIG. 10;

FIG. 12 is an example of a cross-sectional view of the main part during the manufacturing process of the semiconductor device following FIG. 11;

FIG. 13 is an example of a cross-sectional view of a main part during the manufacturing process of the semiconductor device continued from FIG. 12;

FIG. 14 is an example of a cross-sectional view of a main part during the manufacturing process of the semiconductor device continued from FIG. 13;

FIG. 15 is an example of a cross-sectional view of a main part during the manufacturing process of the semiconductor device continued from FIG. 14;

FIG. 16 is an example of a cross-sectional view of a main part in the manufacturing process of the semiconductor device continued from FIG. 15;

FIG. 17 is an example of a cross-sectional view of the main portion of the semiconductor device according to a modification 2 of the first embodiment;

FIG. 18 is an example of a plan view of the main portion of the semiconductor device according to a second modification of the first embodiment;

FIG. 19 is an example of a cross-sectional view showing a configuration example of a semiconductor device for comparison;

FIG. 20 is an example of a cross-sectional view of the main portion of the semiconductor device according to a second embodiment;

FIG. 21 is an example of a cross-sectional view of a main part of the semiconductor device according to the second embodiment.

### DETAILED DESCRIPTION

Hereinafter, a semiconductor device according to each embodiment will be described in detail with reference to the drawings. In the specification and the drawings, the same or corresponding constituent elements are denoted by the same reference numerals, and a repetitive description thereof is omitted. In the drawings, for convenience of description, the configuration may be omitted or simplified. In addition, at least a part of the embodiment and each modification may be arbitrarily combined with each other. In addition, a cross-sectional view may be shown as an end view.

### First Embodiment

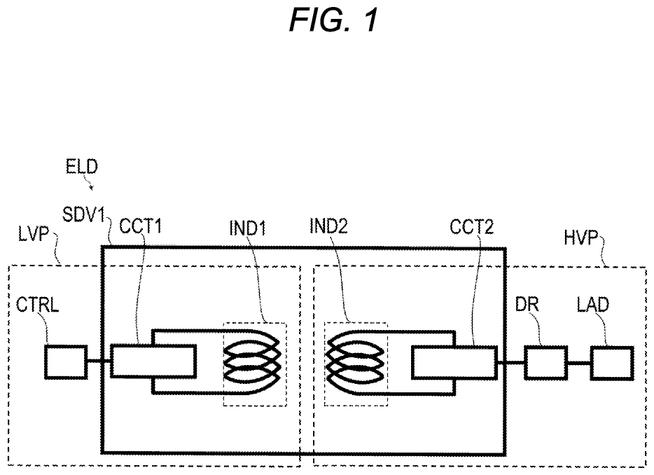

FIG. 1 is a circuit diagram of an electronic device ELD according to a first embodiment. Electronic device ELD includes a control unit CTRL, a semiconductor device SDV1, a drive circuit DR, and a load LAD. The electronic device ELD has a power supply potential (e.g., 5V) on the low potential side, a low potential portion LVP to which a ground potential (e.g., 0V) on the low potential side is supplied, a power supply potential (e.g., 1005V) on the high potential side, and a high potential portion HVP to which a ground potential VSS2 (e.g., 1000V) on the high potential side is supplied. The control unit CTRL, the first circuit CCT1, and the inductor IND1 are included in the low potential unit LVP. Further, the inductor IND2, the second circuit CCT2, the drive circuit DR, and the load LAD is included in the high potential portion HVP.

The control unit CTRL is, for example, a microcomputer (microcontroller, microprocessor). The control unit CTRL generates signals for controlling the loads LADs.

A semiconductor device SDV1 has a first circuit CCT1, an inductor IND1, an inductor IND2, and a second circuit CCT2.

The first circuit CCT1 transmits signals obtained from the control circuit CTRL. The first circuit CCT1, the power supply potential of the low potential side (e.g., 5V), the ground potential of the low potential side (e.g., 0V) is supplied.

The inductor IND1 is electrically connected to the first circuit CCT1. The inductor IND1 is formed so as to be electromagnetically inductively coupled with the inductor IND2. The inductor IND1, similarly to the first circuit CCT1, a power supply potential of the low potential side (e.g., 5V), the ground potential of the low potential side (e.g., 0V) is supplied.

The inductor IND2 is electrically connected to the second circuit CCT2. The inductor IND2 is formed so as to be electromagnetically inductively coupled with the inductor IND1. The inductor IND2 is supplied with a high-potential-side power supply potential (e.g., 1005V) and a high-potential-side grounding potential VSS2 (e.g., 1000V).

The second circuitry CCT2 processes signals received from the inductor IND2. Like the inductor IND2, the second circuit CCT2 is supplied with a power supply potential VDD2 (e.g., 1005V) different from the power supply potential VDD1 and a ground potential VSS2 (e.g., 1000V) different from the ground potential VSS1. The second circuit CCT2 transmits a signal to the drive circuit DR.

The drive circuit DR drives the load LAD in response to the received signal. Exemplary driving circuit DR is a circuit using a power semiconductor such as IGBT (Insulated Gate Bipolar Transistor).

The load LAD is driven by the drive circuit DR. Examples of the load LAD is an electric motor mounted on an electric vehicle or a hybrid vehicle or the like.

Here, the path of the signal in the semiconductor device SDV1 is explained. The signal generated by the first circuit CCT1, by electromagnetic inductive coupling between the inductor IND1 and the inductor IND2, is transmitted to the second circuit CCT2. In other words, the inductor IND1 transmits the signal generated by the control unit CTRL. The inductor IND2 also receives a signal from the inductor IND1. Then, the signal received by the inductor IND2 is transmitted to the second circuit CCT2.

The signal is, for example, a digital signal, but may be an analog signal.

The functions of the first circuit CCT1 and the second circuit CCT2 may be reversed. That is, the second circuit CCT2 may perform transmission, the first circuit CCT1 may perform reception. Further, each of the first circuit CCT1 and the second circuit CCT2 may be configured to be a transceiver circuit capable of performing both transmission and reception.

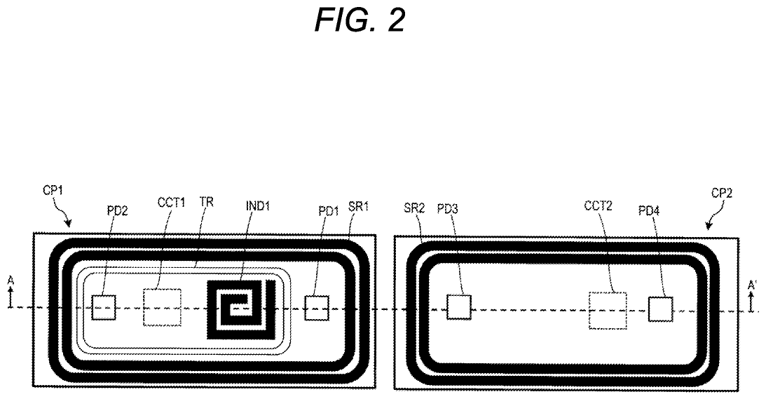

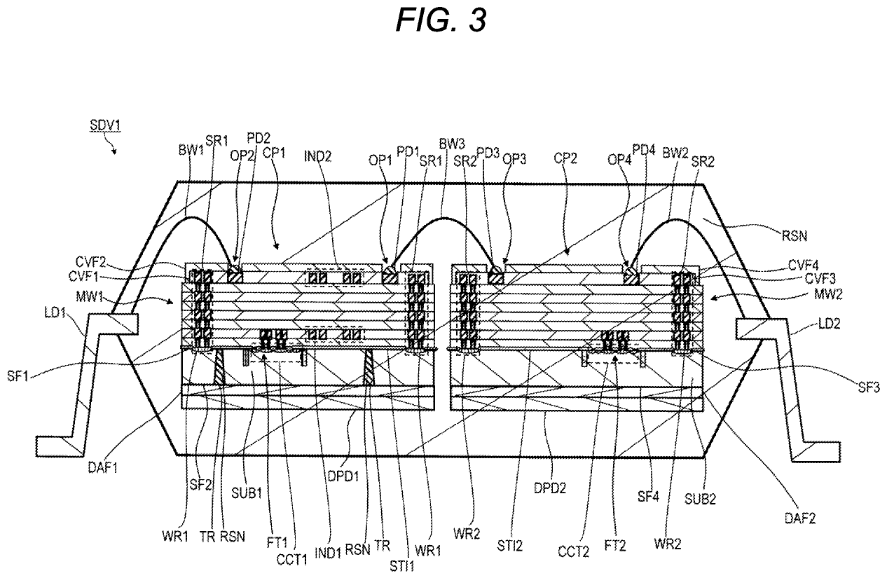

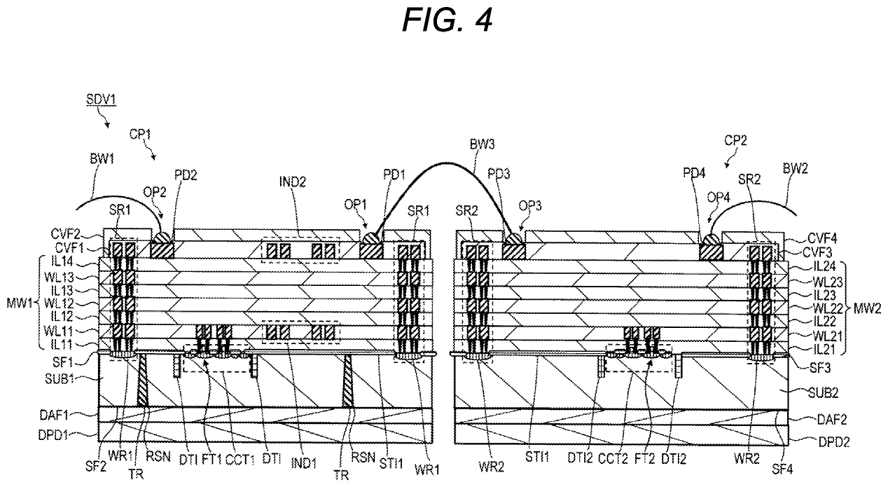

FIG. 2 is a plan view of a main portion of the semiconductor device SDV1. FIGS. 3 and 4 are cross-sectional views of main parts of the semiconductor device SDV1 according to the first embodiment. FIGS. 3 and 4 are cross-sectional views taken along A-A′ line in FIG. 2. The semiconductor device SDV1 includes a semiconductor chip CP1 and a semiconductor chip CP2. Further, the semiconductor chip CP1 and the semiconductor chip CP2, in plan view, of the four sides each has, one side is disposed so as to face each other.

The semiconductor chip CP1 has a semiconductor substrate SUB1, a multilayer wiring layer MW1, a first circuit CCT1, a protective film CVF1, a protective film CVF2. Further, the semiconductor chip CP1 via the bonding material DAF1, is mounted on the die pad DPD1. The semiconductor chip CP1 is electrically connected to the lead LD1 via a bonding wire BW1.

The semiconductor substrate SUB1 is made of a semiconductor such as silicon. The semiconductor substrate SUB1 has a first surface SF1 and the second surface SF2 is a front-back relation to each other. In other words, the first surface SF1 is the surface of the semiconductor substrate SUB1, the second surface SF2 is the back surface of the semiconductor substrate SUB1. The thickness of the semiconductor substrate SUB1 is, for example, 100 μm or more and 700 μm or less. Here, the thickness of the semiconductor substrate SUB1, in the opposing direction in which the first surface SF1 and the second surface SF2 faces each other, the distance between the first surface SF1 and the second surface SF2.

On the semiconductor substrate SUB1, the field-effect transistor FT1, the device separating film STI1 and the well region WR1 are formed. The field effect transistor FT1 is, for example, an n-channel type or p-channel type field effect transistor. A plurality of field-effect transistor FT1 constitutes a first circuit CCT1. Field-effect transistor FT1, on the first surface SF1 of the semiconductor substrate SUB1, is formed in an area surrounded by the device separating film STI1. The isolation film STI1 is, for example, a silicon oxide film, and is formed over a predetermined depth on SUB1 of the semiconductor substrate. Furthermore, around the field-effect transistor FT1, a deep trench insulating groove DTI1 is formed. The deep trench insulating film DTI1 toward the inside of the semiconductor substrate SUB1 from the first surface SF1 of the semiconductor substrate SUB1, a film of an insulator which is formed deeper than the device separating film STI1.

On the first surface SF1 of the semiconductor-substrate SUB1, the multilayer wiring-layer MW1 is formed. The multilayer interconnection layer MW1 has insulating layers IL11 to IL14, interconnection layers WL11 to WL13, an electrode pad PD1, an electrode pad PD2, an inductor IND1, an inductor IND2, and a sealing ring SR1. Insulating layer and the wiring layer, on the first surface SF of the semiconductor substrate SUB1, are overlapped alternately. The lowermost layer of the multilayer wiring layer MW1, the insulating layer IL11 is formed, on the insulating layer IL11, the wiring layer WL11 is formed. On the wiring layer WL11, the insulating layer IL12 is formed. On the insulating layer IL12, the wiring layer WL12 is formed. On the wiring layer WL12, the insulating layer IL13 is formed. On the insulating layer IL13, the wiring layer WL13 is formed. Then, on the wiring layer WL13, the insulating layer IL14 is formed. A protective film CVF1 is formed on the insulating film IL14. The protective film CVF1 is, for example, a silicon nitride film. A protective film CVF2 is formed on the protective film CVF1. The material of the protective film CVF2 is an insulator, and is, for example, a polyimide resin. The protective film CVF2 is formed so as to cover the protective film CVF1. The protective film CVF1 is made of a material having a thermal expansion coefficient intermediate between that of the protective film CVF2 and that of the insulating layer IL14. Thus, when the thermal expansion occurs in the semiconductor chip CP1, it is possible to alleviate the stress generated between the protective film CVF2 and the insulating layer IL14. Inductor IND1 is formed on the interconnect layer WL11. Incidentally, the inductor IND1 may be formed in the wiring layer WL12 or the wiring layer WL13 included in the multilayer wiring layer MW1.

On the insulating layer IL14 is the uppermost layer of the multilayer wiring layer MW1, the electrode pad PD1 and PD2 are formed. The electrode pad PD1 is formed so that a part of the electrode pad PD1 is exposed from the opening OP1 of the protective film CVF1, CVF2. Further, the electrode pad PD1, in plan view, among the four sides of the semiconductor chip CP1 has, are arranged in the vicinity of the sides facing the semiconductor chip CP2. The electrode pad PD1, in plan view, close to the peripheral portion of the semiconductor chip CP1 than the groove TR, and is disposed at a position closer to the center of the semiconductor chip CP1 than the seal ring SR1. Further, the electrode pad PD1, in plan view, is formed at a position different from the first circuit CCT1. The electrode pad PD1 is connected to the bonding wire BW3.

The electrode pad PD2 is formed so that a part of the electrode pad PD2 is exposed from the opening OP2 of the protective film CVF1, CVF2. The electrode pad PD2, in plan view, close to the peripheral portion of the semiconductor chip CP1 than the groove TR, and is disposed at a position closer to the center of the semiconductor chip CP1 than the seal ring SR2. The electrode pad PD2 is connected to the bonding wire BW1. Further, the electrode pad PD1, in plan view, is formed at a position different from the first circuit CCT1. The electrode pad PD2 is connected to the bonding wire BW1.

The inductor IND1 via conductive wires and vias formed in the multilayer wiring layer MW1 is connected to the first circuit CCT1. The inductor IND1 is formed in the interconnect layer WL11.

The inductor IND2 via a bonding wire BW3, is electrically connected to the second circuit CCT2. At FIGS. 3 and 4, the inductor IND1 and the inductor IND2 are formed so as to overlap each other in plan view, may be formed at a position that does not overlap each other in plan view. The inductor IND2 is formed in the protective film CVF1. The inductor IND2 may be formed by rewiring formed on the protective film CVF1. When be formed by rewiring, the material of the inductor IND2 is, for example, copper, the wiring layer inductor IND2 is formed sealing ring SR1 is not formed.

The sealing ring SR1 is composed of a conductive wire and a via formed over a plurality of wiring layers and the insulating layer. The lower end of the sealing ring SR1 is in contact with the well region WR1 of the surface of the semiconductor-substrate SUB1.

The second surface SF2 of the semiconductor-substrate SUB1, the groove TR is formed. The groove TR penetrates the semiconductor substrate SUB1 is formed so as to reach the device separating film STI1 from the back surface of the semiconductor substrate SUB1. The groove TR is along the outer periphery of the semiconductor chip CP1, and is formed between the sealing ring SR1 and the first circuit CCT1 is an internal circuit in a plan view. The groove TR, in plan view, is provided at a position different from the electrode pad PD1. The groove TR is sealed with a resin RSN. The resin RSN is, for example, an insulator such as a polyimide resin. The groove TR, on the outside of the first circuit CCT1, may be provided in multiplexed so as to surround the first circuit CCT1. The width of the groove TR is appropriately adjusted in accordance with a desired withstand voltage. For example, when the desired breakdown voltage is 2000V or more, the width of the groove TR is preferably 5 μm or more and 30 μm or less. Here, the width of the groove TR, in the first plane SF1, in the opposing direction of the inner surface of the two grooves TR facing each other, the distance between the inner surface of the two grooves TR.

The groove TR, the well region WR1 on which the sealing ring SR1 is formed thereon, and a region in which the first circuit CCT1 is formed in the semiconductor substrate SUB1 is electrically insulated. Thus, the potential supplied to the first circuit CCT1 (power supply potential VDD1 and ground potential VSS1) and different potential (i.e., power supply potential VDD2 and ground potential VSS2) is supplied from the inductor IND2, even when the current flows through the side surface of the sealing ring SR1 or the semiconductor chip CP1 to the semiconductor substrate SUB1, the first circuit CCT1 current flows in the first circuit CCT1 it is possible to prevent from being destroyed. In regard to the groove TR, by being provided at a position different from the electrode pad PD1, it is possible to reduce the effect of crimping during bonding. Further, when a plurality of groove TRs are provided, the dielectric strength of the semiconductor chip CP1 can be increased as compared with the case where only one groove TR is provided.

The first circuit CCT1, whereas the power supply potential VDD1 and the ground potential VSS1 is supplied, the potential of the well region WR1 is floating. That is, the well region WR1, the power supply potential VDD1 or ground potential VSS1 is supplied to the first circuit CCT1, neither is supplied. Thus, for example, as compared with the case where the power supply potential WR1 or ground potential VDD1 to the well region VSS1 is supplied, it is possible to prevent a large potential difference occurs between the well region WR1 and the power supply potential VDD2 and the ground potential VSS2 supplied to the inductor IND2. Consequently, it is effective to prevent dielectric breakdown occurs between the inductor IND2 and the semiconductor-substrate SUB1.

The semiconductor chip CP2 has a semiconductor substrate SUB2, a multilayer wiring layer MW2, a second circuit CCT2, a protective film CVF3, a protective film CVF4. Further, the semiconductor chip CP2 via the bonding material DAF2, is mounted on the die pad DPD2. The semiconductor chip CP2 is electrically connected to the lead LD2 via a bonding wire BW2.

The semiconductor substrate SUB2 is made of a semiconductor such as silicon. The semiconductor substrate SUB2 has a third surface SF3 and the fourth surface SF4 is a front-back relation to each other. In other words, the third surface SF3 is the surface of the semiconductor substrate SUB2, the fourth surface SF4 is the back surface of the semiconductor substrate SUB2. The thickness of the semiconductor substrate SUB2 is, for example, 100 μm or more and 700 μm or less. Here, the thickness of the semiconductor substrate SUB2, in the thickness direction of the semiconductor substrate SUB2, the distance between the third surface SF3 and the fourth surface SF4.

On the semiconductor-substrate SUB2, the field-effect transistor FT2, the device separating film STI2, and the well region WR2 is formed.

The field effect transistor FT2 is, for example, an re-channel type field effect transistor or a p-channel type field effect transistor. A plurality of field-effect transistor FT2 constitutes a second circuit CCT2. Field-effect transistor FT2, on the third surface SF3 of the semiconductor substrate SUB2, is formed in an area surrounded by the device separating film STI2. Furthermore, around the field-effect transistor FT2, a deep trench insulating film DTI2 is formed. The deep trench insulating film DTI2 is an insulating film formed deeper than the element separation film STI2 from the third surface SF3 of the semiconductor substrate SUB2 toward the inside of the semiconductor substrate SUB2.

The element isolating film STI2 is, for example, an insulator such as a silicon oxide film is formed over a predetermined depth from the surface of the semiconductor substrate SUB2.

On the third surface SF3 of the semiconductor substrate SUB2, the multilayer wiring-layer MW2 is formed. The multilayer interconnection layer MW2 has insulating layers IL21 to IL24, interconnection layers WL21 to WL23, an electrode pad PD3, an electrode pad PD4, and a sealing ring SR2. A protective film CVF3 is formed on the insulating film IL24. A protective film CVF4 is formed on the protective film CVF3. The protective film CVF4 is an insulator, and is, for example, a polyimide resin. The protective film CVF4 is formed so as to cover the protective film CVF3. Incidentally, the inductor IND2 may be provided in the wiring layer included in the multilayer wiring layer MW2.

On the insulating layer IL24 is the uppermost layer of the multilayer wiring layer MW2, the electrode pad PD3 and PD4 are formed. The electrode pad PD3 is formed so that a part of the electrode pad PD3 is exposed from the opening OP3 of the protective film CVF3, CVF4. Further, the electrode pad PD3 is arranged in the vicinity of the side facing the semiconductor chip CP1 among the four sides of the semiconductor chip CP2 in a plan view. The electrode pad PD3, in plan view, is formed at a position different from the second circuit CCT2. The electrode pad PD3 is connected to the bonding wire BW3.

The electrode pad PD4 is formed so that a part of the electrode pad PD4 is exposed from the opening OP4 of the protective film CVF1, CVF2. The electrode pad PD4 is connected to the bonding wire BW2. Further, the electrode pad PD4, in plan view, is formed at a position different from the second circuit CCT2. The electrode pad PD4 is connected to the bonding wire BW2.

The electrode pad PD3 of the electrode pad PD1 and the semiconductor chip CP2 of the semiconductor chip CP1, via a bonding wire BW3, are electrically connected to each other.

The semiconductor chip CP1, semiconductor chip CP2, bonding wire BW1, bonding wire BW2, and bonding wire BW3 are sealed by the sealing resin MR.

Next, a manufacturing process of the semiconductor device SDV1 of the first embodiment will be described. The manufacturing process of the semiconductor device SDV1 includes the following steps S1 to S9.

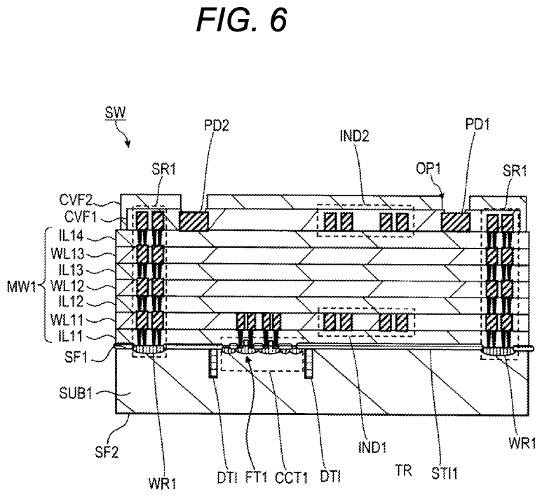

(Step S1; semiconductor wafer SW preparation step) First, as shown in FIG. 6, a semiconductor wafer SW having a semiconductor substrate SUB1, a first circuit CCT1, and a multilayer wiring layer MW1 including an inductor IND1. As a method of forming the semiconductor wafer SW, known methods in the art of digital isolators may be employed.

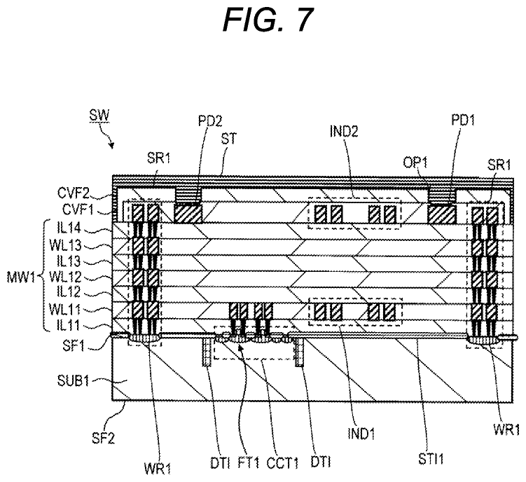

(Step S2; Sheet Attachment Step) Next to Step S1, as shown in FIG. 7, a sheet ST having tackiness is adhered on the protective film CVF2 The material of the sheet ST is, for example, vinyl chloride. Thereafter, the sheet ST is adhered to a support (not shown) The support is made of a material which is transmitted through ultraviolet rays because the sheet ST is peeled off. If the thickness of the sheet ST is 100 μm or more, the support is unnecessary.

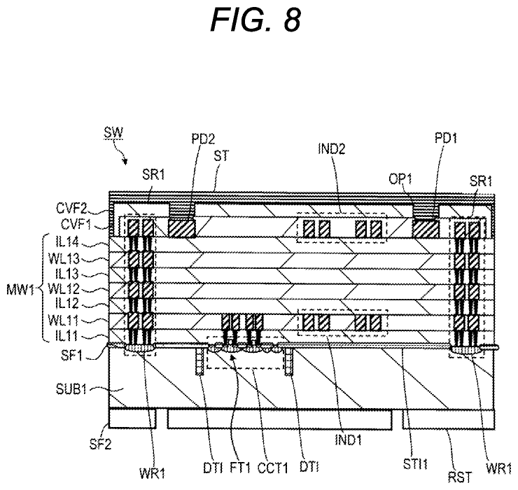

(Step S3; groove forming step) Next in step S2, as shown in FIG. 8, the photoresist pattern RST is formed on the second surface SF2 of the semiconductor substrate SUB1. The photoresist pattern RST is formed so as to cover other regions of the back surface of the semiconductor substrate while exposing the position where the groove should be formed.

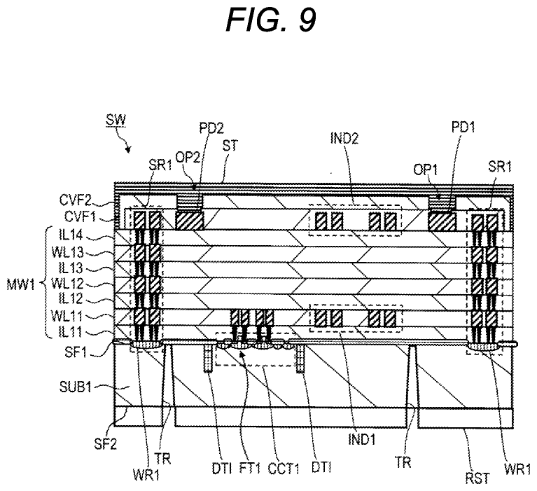

(Step S4; etching step) Next, as shown in FIG. 9, the photoresist pattern RST as an etching mask, etching process is performed on the semiconductor substrate SUB1, so as to surround the first circuit CCT1, the second surface SF2 of the semiconductor substrate SUB1 trench TR reaching to the device separating film STI1 is formed. Incidentally, the groove TR may be formed so as to reach from the second surface SF2 of the semiconductor substrate SUB1 to the insulating layer IL11. Examples of etching methods for semiconductor substrate SUB1 include dry etching and wet etching methods. Examples of etchants used in the wet etching method include potassium hydroxide (KOH) aqueous solution, tetramethylammonium hydroxide (TMAH) aqueous solution, ethylenediamine-pyrocatel (EDP) aqueous solution, hydrazine (N2H4) aqueous solution, sodium hydroxide aqueous solution and cesium hydroxide (CsOH) aqueous solution. The groove TR is along the outer periphery of the semiconductor chip CP1, and is formed between the first circuit CCT1 and the well region WR1. Further, the grooves TR may be provided in a plurality of grooves so that one groove surrounds the other groove in the bottom view.

When the groove TR is formed by a wet etching method, since the etching rate varies depending on the crystal orientation of the semiconductor substrate SUB1, the cross-sectional view of the groove TR is a so-called trapezoidal shape. That is, in a cross section perpendicular to the extending direction of the groove TR, the width of the groove TR in the first plane SF1 is smaller than the width of the groove TR in the second plane SF2. Furthermore, in the above sectional-section, the width of the groove TR is continuously increased as approaching the second surface SF2 from the first surface SF1. For example, the side surface of the groove TR, the angle constituted by the first surface SF1 of the semiconductor substrate SUB1 is about 50°. Thus, it can be estimated that the penetrating portion PP was formed by the wet etching method.

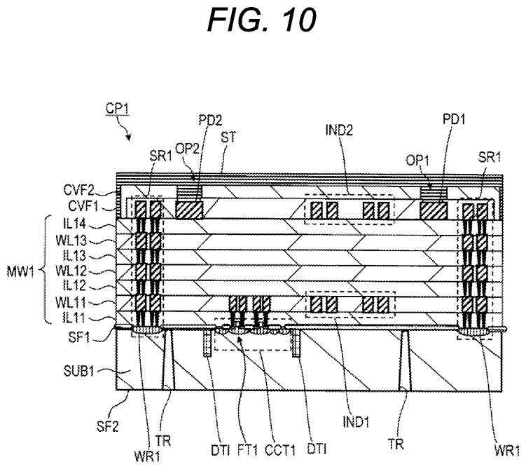

Next, as shown in FIG. 10, the photoresist pattern RST is removed. Then, the semiconductor wafer SW is diced to obtain a plurality of singulated semiconductor chips CP1.

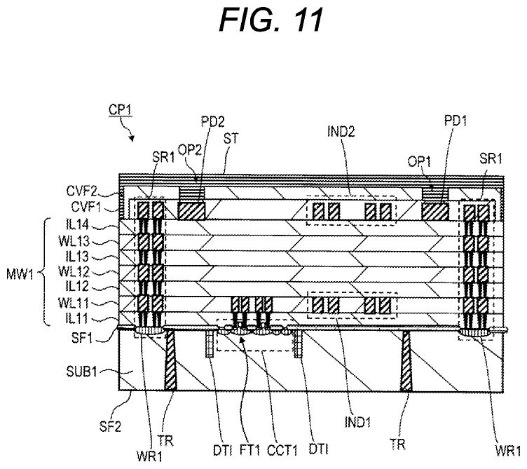

(Step S5; resin sealing step) Next in the step S4, as in FIG. 11, sealed with a groove TR resin RSN (see FIG. 4). The resin RSN is, for example, a resin of an insulator such as a polyimide resin. Examples of encapsulation methods include lithography, mosquito, and nanoimprint methods. For example, a resin RSN may be formed by curing the curable composition after providing the curable composition constituting the resin RSN into the groove TR The above curable composition may be a thermosetting composition or a photocurable composition.

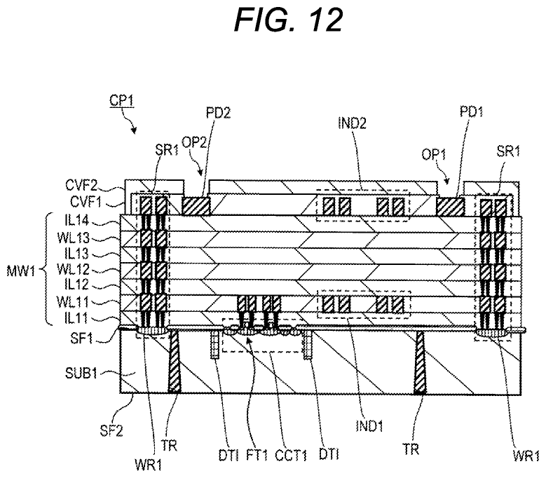

Next, as shown in FIG. 12, the sheet ST is peeled off, and the semiconductor chip CP1 is separated from the support. As a method of peeling the sheet ST, for example, a method of irradiating the sheet ST with ultraviolet rays via a support transmitting ultraviolet rays is available.

(Step S6; semiconductor chip CP2 preparing step) Next, preparing the semiconductor chip CP2. The semiconductor chip CP2 includes a semiconductor substrate SUB2, a second circuit CCT2, and a multilayer wiring layer MW2 including an inductor IND2.

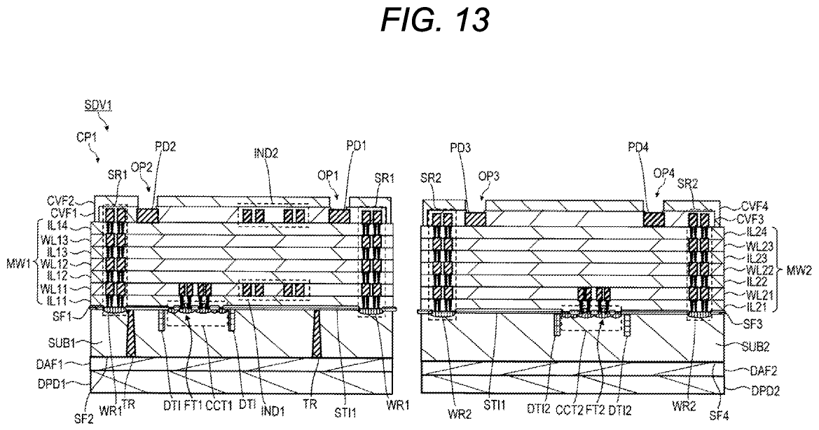

(Step S7; junction step) Next, as shown in FIG. 13, the semiconductor chip CP1 is bonded to the die pad DPD1 by the bonding material DAF1. Further, the semiconductor chip CP2 is bonded to the die pad DPD2 by the bonding material DAF2.

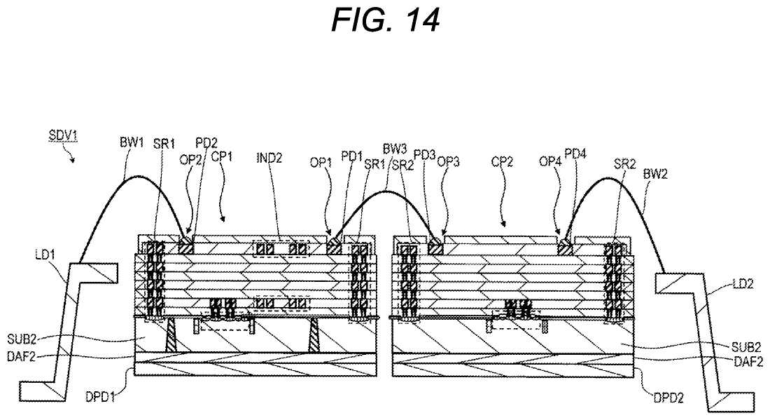

(Step S8; bonding step) Next, as in FIG. 14, by the bonding wire BW1, connecting the electrode pad PD2 and the lead LD1 of the semiconductor chip CP1. Further, the bonding wire BW2 connects the electrode pad PD4 and the lead LD2 of the semiconductor chip CP2. Furthermore, the bonding wire BW3 connects the electrode pad PD3 of the electrode pad PD1 and the semiconductor chip CP2 of the semiconductor chip CP1.

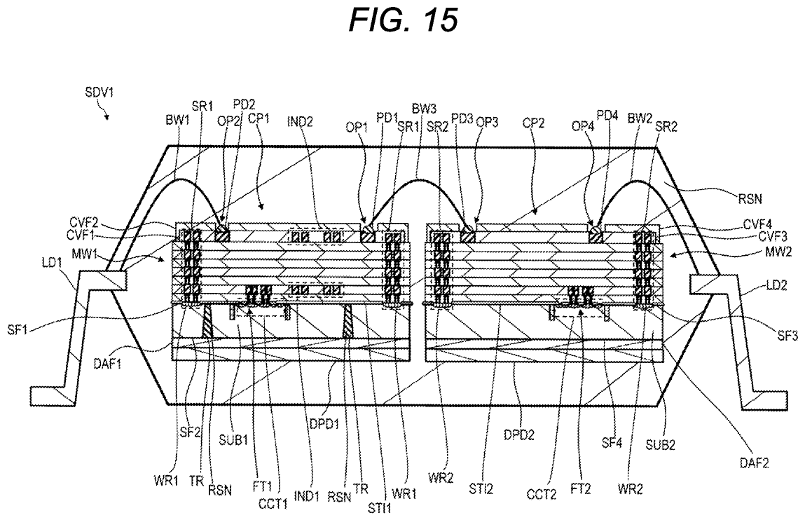

(Step S9; sealing step) Next, as in FIG. 15, the semiconductor chip CP1, the semiconductor chip CP2, the die pad DPD1, the die pad DPD2, and the bonding wire BW3, sealed by a resin RSN.

As described above, the semiconductor device SDV1 according to the first embodiment is formed.

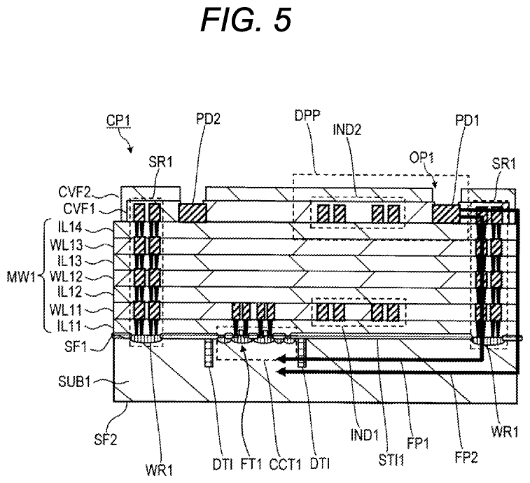

FIG. 5 is a cross-sectional view showing the configuration of a semiconductor device of the comparative example. In the semiconductor chip CP1, the electrode pad PD1 and the inductor IND2, a potential different from the potential supplied to the first circuit CCT1 of the semiconductor chip CP1 is supplied. Here, referred to as different potential supplying unit DPP collectively electrode pad PD1 and the inductor IND2. In FIG. 5, in the different potential supply unit DPP, the electrode pad PD1 is arranged at a position closer to the peripheral edge of the semiconductor chip CP1 than the inductor IND2.

The inventor has found a problem that dielectric breakdown occurs in a path leading to the semiconductor-substrate SUB1 through the surface of the seal ring or the multilayer wiring layer MW1 from the different potential supply unit DPP. For example, as shown by the arrows in FIG. 5, dielectric breakdown may occur in path FP1 and path FP2. The path FP1 is a path from the electrode pad PD1 to the first circuit CCT1 on the semiconductor substrate SUB1 via the seal ring SR1. The path FP2 is a path from the electrode pad PD1 to the semiconductor substrate SUB1 via the side surface of the multilayer wiring layer MW1. Since a different potential supply unit DPP is supplied to the first circuit CCT1 on the semiconductor substrate SUB1, a large current may flow by dielectric breakdown. There is a possibility that the first circuit CCT1 is destroyed.

On the other hand, in the first embodiment, as described above, the grooves TRs are provided around the first circuit CCT1. Thus, it is possible to prevent the current from flowing from the electrode pad PD1 to the first circuit CCT1 through the outer periphery or the sealing ring SR1 of the semiconductor chip CP1, to improve the dielectric strength of the semiconductor chip CP1, it is possible to improve the reliability.

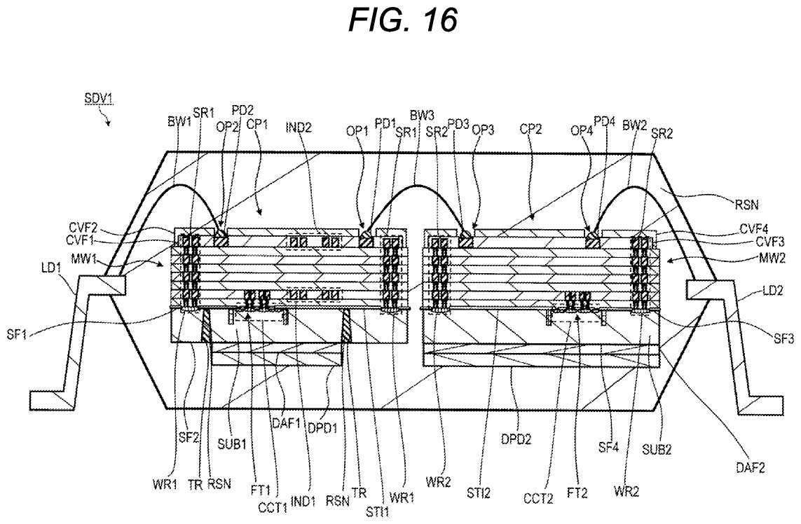

(First modification of the first embodiment) FIG. 16 is a cross-sectional view of a main part of a semiconductor device according to a first modification of the first embodiment.

A die pad DPD1, at a position inside the semiconductor substrate SUB1 than the groove TR, is bonded to the second surface SF2 of the semiconductor substrate SUB1. That is, the die pad DPD1, at a position different from the groove TR, is bonded to the second surface SF2 of the semiconductor substrate SUB1.

In the first modification, the groove TR can be sealed together with the semiconductor chip CP1, the semiconductor chip CP2, the die pad DPD1, and the die pad DPD2. There is an effect that an interface does not occur between the resin REN in the groove TR and the resin RSN outside the semiconductor chip CP1.

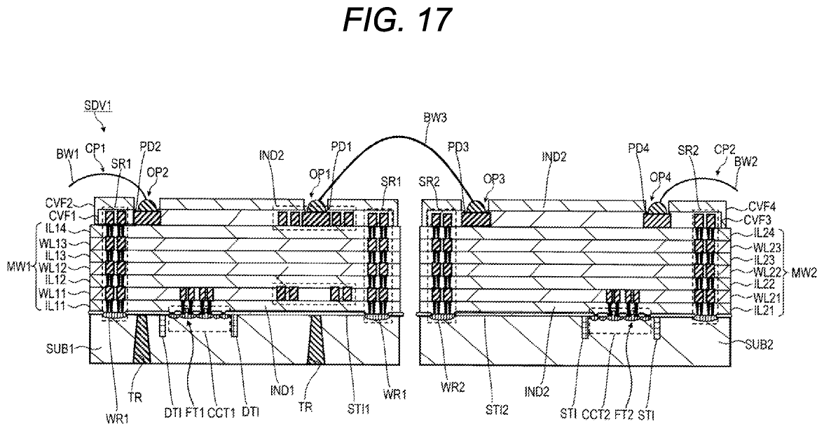

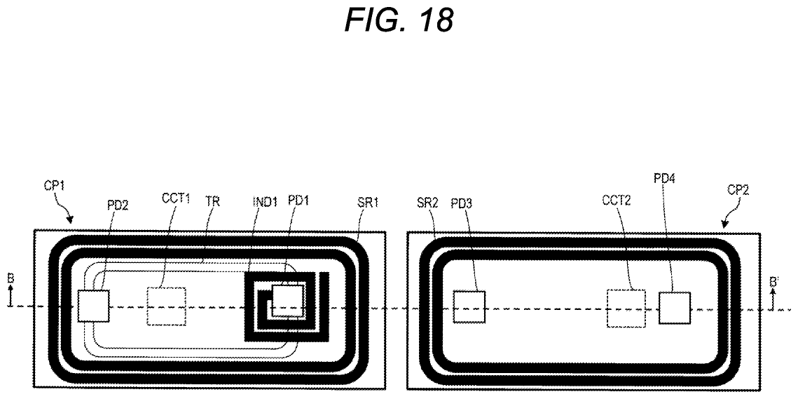

(Second modification of the first embodiment) FIG. 18 is a cross-sectional view showing an example of a configuration of a semiconductor device according to a second modification. FIG. 17 is a cross-sectional view showing an example of a configuration of a semiconductor device according to the second modification. FIG. 18 is a plan view showing an example of the configuration of a semiconductor device according to the second modification. FIG. 17 is a cross-sectional view taken along B-B′ line in FIG. 18. Differences between the semiconductor device according to the first embodiment and the semiconductor device according to the second modification will be described below.

As shown in FIGS. 17 and 18, in the semiconductor device according to Modification 2, the electrode pad PD1 is provided at the center of the inductor IND2. That is, the electrode pad PD1 is provided so as to be surrounded by the inductor IND2.

Groove TR is provided at a position overlapping the electrode pad PD1. The width of the groove TR is smaller than the electrode pad PD1, the width of the groove TR may be larger than the electrode pad PD1.

In the second modification, the space at the center of the inductor IND2 is used, and the electrode pad PD1 is arranged so as to be surrounded by the inductor IND2 in a plan view. As a result, the area of the semiconductor chip CP1 can be reduced as compared with the case where the electrode pad PD1 is provided outside the inductor IND2. In the semiconductor device SDV1 of the second modification, as in the semiconductor device SDV1 of the first embodiment, the current flows from the inductor IND2 to the first circuit CCT1 as a transmission circuit via the outer periphery of the semiconductor chip CP1 or the seal ring. This can be prevented and the dielectric strength of the semiconductor chip CP1 can be improved.

### Second Embodiment

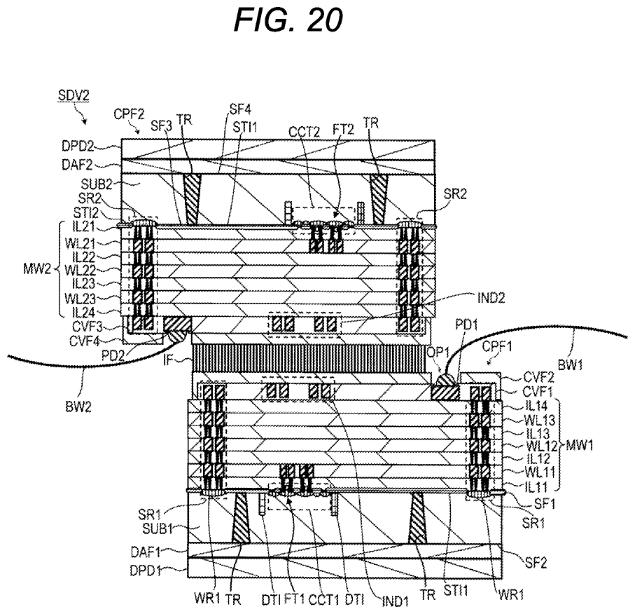

FIG. 20 is a cross-sectional view of a semiconductor device SDV2 according to the second embodiment. Hereinafter, a difference between the semiconductor device SDV2 of the second embodiment and the semiconductor device SDV1 according to the first embodiment will be described.

The semiconductor device SDV2 according to the second embodiment has a structure (Face to Face structure) in which the semiconductor chip CPF1 and the semiconductor chip CPF2 face each other on the surface via the insulating film IF which is an interchip insulating film.

The semiconductor chip CPF1 has a semiconductor substrate SUB1, a multilayer wiring layer MW1, a first circuit CCT1, a protective film CVF1, a protective film CVF2.

On the insulating layer IL14 is the uppermost layer of the multilayer wiring layer MW1 included in the semiconductor chip CPF1, the electrode pad PD1 is formed. The electrode pad PD1 is formed so that a part of the electrode pad PD1 is exposed from the opening OP1 of the protective film CVF1, CVF2. Further, the electrode pad PD1, in plan view, among the four sides of the semiconductor chip CPF1 has, are arranged in the vicinity of the sides facing the semiconductor chip CPF2. The electrode pad PD1, in plan view, close to the peripheral portion of the semiconductor chip CPF1 than the groove TR, and is disposed at a position closer to the center of the semiconductor chip CPF1 than the seal ring SR1. Further, the electrode pad PD1, in plan view, is formed at a position different from the first circuit CCT1. The electrode pad PD1 is connected to the bonding wire BW1.

The multi-layer interconnection-layer MW1 has an inductor IND1 but does not have an inductor IND2. Although the inductor IND1 is formed in the protective film CVF1, it may be formed in the wiring layers WL11, WL12, or WL13 of the multilayer wiring layer.

The semiconductor chip CPF2 has a semiconductor substrate SUB2, a multilayer wiring layer MW2, a second circuit CCT2, a protective film CVF3 and a protective film CVF4.

The multilayer interconnection-layer MW2 has an inductor IND2. Although the inductor IND2 is formed in the protective film CVF3, it may be formed in the wiring layer WL21, WL22, or WL23 of the multilayer wiring layer.

The semiconductor chip CPF1 is bonded to the die pad DPD1 through the bonding material DAF1.

The semiconductor chip CPF2 is bonded to the die pad DPD1 through the bonding material DAF2.

The semiconductor substrate SUB1 of the semiconductor chip CPF2, the groove TR is provided. The groove TR penetrates the semiconductor substrate SUB1 and is formed so as to reach the device separating film STI1 from the back surface of the semiconductor substrate SUB1. The groove TR is along the outer periphery of the semiconductor chip CP1, and is formed between the sealing ring SR1 and the first circuit CCT1 is an internal circuit in a plan view. The groove TR, in plan view, is provided at a position different from the electrode pad PD1. The groove TR is sealed with a resin RSN. The resin RSN is, for example, an insulator such as a polyimide resin. The groove TR, on the outside of the first circuit CCT1, may be provided in multiplexed so as to surround the first circuit CCT1. The width of the groove TR is appropriately adjusted in accordance with a desired withstand voltage. For example, when the desired breakdown voltage is 2000V or more, the width of the groove TR is preferably 5 μm or more and 30 μm or less. Here, the width of the groove TR is the distance of the inner surface of the groove TR in the first surface SF1.

The groove TR, the well area WR1 on which the seal ring is formed, and a region in which the first circuit CCT1 is formed in the semiconductor substrate SUB1 is electrically insulated. Thus, the potential supplied to the first circuit CCT1 (power supply potential VDD1 and ground potential VSS1) and different potential (i.e., power supply potential VDD2 and ground potential VSS2) is supplied from the inductor IND2, even when the current flows through the side surface of the sealing ring SR1 or the semiconductor chip CP1 to the semiconductor substrate SUB1, the first circuit CCT1 current flows in the first circuit CCT1 it is possible to prevent from being destroyed. By providing the groove TR at a position different from that of the electrode pad PD1, the influence of crimping during bonding can be reduced. Further, when the grooves TR are provided in multiple positions, the withstand voltage of the semiconductor chip CPF1 can be increased as compared with the case where only one groove TR is provided.

A method of manufacturing a semiconductor device according to the second embodiment will be described.

Prepare the semiconductor chip CPF1 and the semiconductor chip CPF2 in the same manner as steps S1 to S6 in the first embodiment.

(Step S10; junction step) Next in step S6, using a bonding material DAF1, DAF2, the semiconductor chip CPF1 and the semiconductor chip CPF2, the first surface SF1 and the third surface SF3 is bonded so as to face. Examples of bonding material DAF1, DAF2 include insulators such as die attachment films.

(Step S11; bonding step) After step S10, the electrode pad PD1 and the first lead (not shown) are connected to each other using the bonding wire BW1. The electrode pad PD2 and the second lead (not shown) are connected to each other using the bonding wire BW2. The first lead is a conductive member for electrically connecting the first circuit CCT1 and an external circuit (not shown). The second lead is a conductive member for electrically connecting the external circuit (not shown) and the second circuit CCT2.

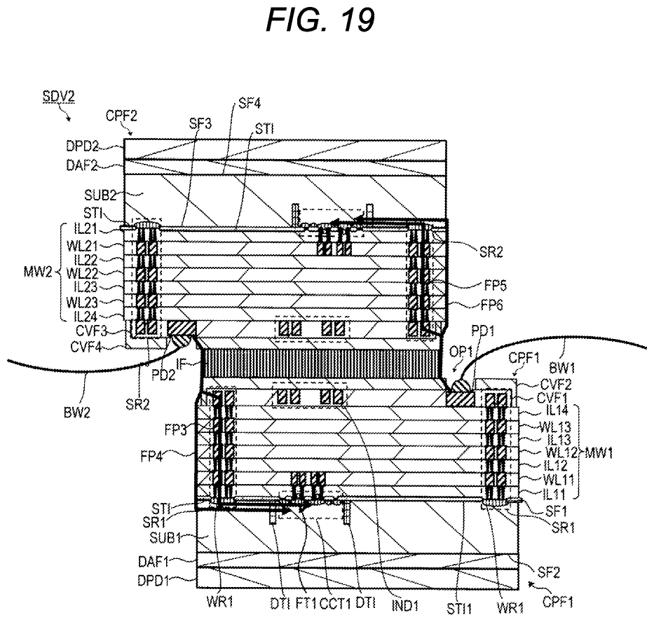

FIG. 19 is a fragmentary cross-sectional view of a comparative semiconductor device SDV2. Unlike the semiconductor device according to the first embodiment, in the semiconductor device SDV2 for comparative, via the insulating film IF, and the third surface SF3 of the first surface SF1 and the semiconductor chip CPF2 of the semiconductor chip CPF1 is bonded so as to face each other. Further, the inductor IND2 is not formed on the semiconductor chip CPF1, the inductor IND2 is formed on the semiconductor chip CPF2. Then, the semiconductor chip CPF1, the groove TR (see FIG. 20) is not formed.

The inventor has found in the semiconductor device SDV2 for comparative, a problem that dielectric breakdown occurs in a path leading to the semiconductor substrate SUB1, SUB2 through the side surface of the sealing ring SR1, SR2 or the multilayer wiring layer MW1, MW2 from the electrode pad PD1, PD2. For example, as shown by the arrows in FIG. 19, dielectric breakdown may occur in path FP3 or path FP4. The path FP3 is a path from the electrode pad PD2 to the first circuit CCT1 on the semiconductor substrate SUB1 via the seal ring SR1. The path FP4 is a path from the electrode pad PD2 to the first circuit CCT1 on the semiconductor substrate SUB1 via the side surface of the multilayer wiring layer MW1. In addition, dielectric breakdown may occur in path FP5 or path FP6. The path FP5 is a path from the electrode pad PD1 to the second circuit CCT2 on the semiconductor substrate SUB2 via the seal ring SR2. The path FP6 is a path from the electrode pad PD1 to the second circuit CCT2 on the semiconductor substrate SUB2 via the side surface of the multilayer wiring layer MW2. A potential different from that of the electrode pad PD2 is supplied to the first circuit CCT1 on the semiconductor substrate SUB1. Further, a potential different from that of the electrode pad PD1 is supplied to the second circuit CCT2 on the semiconductor substrate SUB2. Therefore, if dielectric breakdown occurs in the above-mentioned path, a large current may flow and the first circuit CCT1 and the second circuit CCT2 may be destroyed.

In the second embodiment, as described above, by providing the groove TR around the first circuit CCT1, it is possible to prevent the current from flowing from the electrode pad PD2 to the first circuit SR1 on the semiconductor substrate MW1 through the side surface of the sealing ring MW1 or the multilayer wiring layer SR1, the semiconductor chip it is possible to improve the dielectric strength of CP1. Further, by providing the groove TR around the second circuit CCT2, it is possible to prevent the current flows from the electrode pad PD1 to the second circuit SR2 on the semiconductor substrate MW2 through the side surface of the sealing ring MW2 or the multilayer wiring layer SR2, the semiconductor chip it is possible to improve the dielectric strength of CP2.

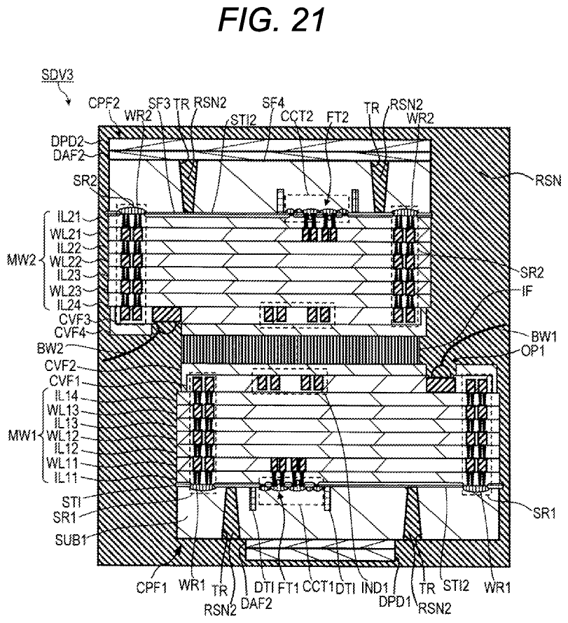

(First modification of the second embodiment) in FIG. 21 shows a fragmentary cross-sectional view of a semiconductor device SDV3 according to a first modification of the second embodiment. A die pad DPD1, at a position inside the semiconductor substrate SUB1 than the groove TR, is bonded to the second surface SF2 of the semiconductor substrate SUB1. That is, the die pad DPD1, at a position different from the groove TR, is bonded to the second surface SF2 of the semiconductor substrate SUB1. Further, the die pad DPD2, at a position inside the semiconductor substrate SUB2 than the groove TR, is bonded to the fourth surface SF4 of the semiconductor substrate SUB2. That is, the die pad DPD2, at a position different from the groove TR, is bonded to the fourth surface SF4 of the semiconductor substrate SUB1.

In the first modification, the groove TR can be sealed together with the semiconductor chip CP1, the semiconductor chip CP2, the die pad DPD1, and the die pad DPD2. This has an effect that no interface is formed between the resin RSN2 in the groove TR and the resin RSN outside the semiconductor chip CPF1.

It should be noted that the present invention is not limited to the above-mentioned embodiments, and various modifications can be made without departing from the gist thereof.

In addition, even when a specific numerical value example is described, it may be a numerical value exceeding the specific numerical value, or may be a numerical value less than the specific numerical value, except when it is theoretically obviously limited to the numerical value.

What is claimed is:

1. A semiconductor device comprising:
a first semiconductor substrate having a first surface and a second surface which is formed on the other side of the first surface;
a first circuit formed on the first surface;
a first inductor electrically connected to the first circuit and formed overlapping the first semiconductor substrate;
a second semiconductor substrate having a third surface and a fourth surface which is formed on the other side of the third surface;
a second circuit formed on the third surface;
a second inductor electrically connected to the second circuit and configured to be electromagnetically inductive coupling with the first inductor;
wherein, in the second surface, a groove penetrating the first semiconductor substrate is formed in a plan view, and
wherein the groove is formed by surrounding the first circuit in plan view.

2. The semiconductor device according to claim 1, further comprising:
a first semiconductor chip including the first semiconductor substrate, the first inductor and the second inductor; and
a second semiconductor chip including the second semiconductor substrate and the second circuit.

3. The semiconductor device according to claim 1,
wherein the first inductor and the second inductor are formed at positions overlapping each other in plan view.

4. The semiconductor device according to claim 1,
wherein the first circuit is supplied with a first reference voltage; and
wherein the second circuit is supplied with a second reference voltage whose potential is different from that of the first reference voltage.

5. The semiconductor device according to claim 2,
wherein the first semiconductor chip further comprises a first multilayer wiring layer formed on the first surface,
wherein the first semiconductor substrate further comprises a first well region formed in the first surface,
wherein the first multilayer wiring layer has a first seal ring formed on the first well region,
wherein the groove is formed between the first circuit and the first seal ring in plan view.

6. The semiconductor device according to claim 5,
wherein the first circuit is supplied with a first reference voltage, and
wherein a potential of the first well region is floating.

7. The semiconductor device according to claim 2,
wherein the second semiconductor chip includes the second inductor, and
wherein the first semiconductor chip and the second semiconductor chip are bonded to each other such that the first surface and the third surface oppose each other with an inter-chip insulating film interposed therebetween.

8. The semiconductor device according to claim 5, further comprising a first insulating film formed by covering the first surface between the first multilayer wiring layer and the first surface,
wherein the groove is formed by extending from the second surface to the first insulating film.

9. The semiconductor device according to claim 5,
wherein the first semiconductor chip further comprises a bonding pad formed on the uppermost layer of the first multilayer wiring layer, and
wherein the groove is formed at a position not overlapping from the bonding pad in a plan view.

10. The semiconductor device according to claim 1,
wherein the groove is sealed with a resin.

11. A semiconductor device comprising:
a first semiconductor substrate having a first surface and a second surface which is formed on the other side of the first surface;
a first circuit formed on the first surface;
a first inductor electrically connected to the first circuit;
a first multilayer wiring layer formed on the first surface;
a second semiconductor substrate having a third surface and a fourth surface which is formed on the other side of the third surface;
a second circuit formed on the third surface;
a second multilayer wiring layer formed on the third surface,
a second insulating film formed between the third surface and the second multilayer wiring layer
a second inductor electrically connected to the second circuit and configured to transmit or receive a signal between the first inductor; and
a groove reaching the first insulating film from the second surface,
wherein the groove is formed along the outer periphery of the first chip.

12. The semiconductor device according to claim 11,
wherein the first inductor and the second inductor are formed by overlapping each other in plan view.

13. The semiconductor device according to claim 12,
wherein the first inductor and the second inductor are formed by overlapping each other in plan view.

14. The semiconductor device according to claim 11,
wherein the second chip includes the second inductor, and
wherein the first chip and the second chip overlap with each other in a direction in which the first surface and the third surface oppose each other with an inter-chip insulating film interposed therebetween.

15. The semiconductor device of claim 11,
wherein the groove is formed multiple and surrounding the first circuit.

16. The semiconductor device according to claim 11,
wherein the first chip further comprises a bonding pad formed on an uppermost layer of the first multilayer wiring layer, and
wherein the groove is formed at a position not overlapping the bonding pad in a plan view.

17. A method of manufacturing a semiconductor device, comprising:
(a) preparing a first semiconductor chip comprising:
a first semiconductor substrate having a first surface and a second surface which is formed on the other side of the first surface;
a first circuit formed on the first surface;
a first inductor electrically connected to the first circuit;
a first multilayer wiring layer formed on the first surface;
a first insulating film formed between the first surface and the first multilayer wiring layer;
(b) preparing a second semiconductor chip comprising:
a second semiconductor substrate having a third surface and a fourth surface which is formed on the other side of the third surface;
a second circuit formed on the third surface;
a second multilayer wiring layer formed on the third surface; and
a second insulating film formed between the third surface and the second multilayer wiring layer;
(c) preparing a second inductor electrically connected to the second circuit;
(d) forming a groove extending from the second surface to the first insulating film.

18. The method according to claim 17,
wherein a first semiconductor chip further comprising a first seal ring formed in the first multilayer wiring layer, and
wherein the groove is formed between the first circuit and the first seal ring.

19. The method according to claim 17, further comprising:
(e) sealing the first semiconductor chip and the second semiconductor chip with a resin.
